(19) United States
(12) Patent Application Publication
(10) Pub. No.: US 2017/0040186 A1
(43) Pub. Date: Feb. 9, 2017

(54) SEMICONDUCTOR DEVICE AND METHOD OF MANUFACTURING THE SAME

(71) Applicant: SII Semiconductor Corporation, Chiba-shi (JP)

(72) Inventor: Shinya KUBOTA, Chiba-shi (JP)

(21) Appl. No.: 15/225,241

(22) Filed: Aug. 1, 2016

(30) Foreign Application Priority Data
Aug. 3, 2015 (JP) 2015-153577

(51) Int. Cl. H01L 21/56; H01L 23/495; H01L 21/48; H01L 23/29

(52) U.S. Cl. CPC H01L 21/565; H01L 23/293; H01L 23/4952; H01L 23/49575; H01L 21/4825

(57) ABSTRACT

Provided is a method of manufacturing a semiconductor device with sufficient heat dissipation property, in which a mold configured to mold an island for mounting a semiconductor chip thereon includes an inner punch (10), punch guides (11), and outer punches (12), and in which a recessed portion (14), protruding walls (8), and thin walled portions (9) of the island are formed through pressing of the mold. A front surface and side surfaces of the island, the thin walled portions, the semiconductor chip, inner leads, and wires are encapsulated by resin while a rear surface of the island is exposed from the resin.

### BACKGROUND OF THE INVENTION

1. Field of the Invention

The present invention relates to a semiconductor device in which an island for mounting a semiconductor chip thereon has a rear surface that is exposed from an encapsulating resin, and to a method of manufacturing the semiconductor device.

2. Description of the Related Art

In general, in a semiconductor device with high heat dissipation property in which an island for mounting a semiconductor chip thereon has a rear surface that is exposed from an encapsulating resin, when the encapsulating resin fills the cavity of the encapsulating mold while a rear surface of the element mounting portion is pressed against the encapsulating mold, the encapsulating resin may flow into a portion between the rear surface of the element mounting portion and the encapsulating mold, thereby causing thin burrs to occur on a rear surface side of the island. In this case, there is a problem in that the reduction of an effective area of the exposed portion on the rear surface side of the island causes a decrease in the heat dissipation effect.

Measures are thus taken to prevent the thin burrs from entering a central part of a rear surface portion of the island by forming a recessed shape (recess) on a rear surface side of the island and forming protruding walls on the rear surface of the island so that the pressing force of the protruding walls against a lower mold increases during encapsulation (see, for example, Japanese Patent Application Laid-open No. 2013-175795).

However, as disclosed in Japanese Patent Application Laid-open No. 2013-175795, by forming the recessed shape (recess) on the rear surface side of the island, entrance of the thin burrs to the rear surface of the island can be suppressed to a certain degree, but is not completely suppressed. Further, depending on the form of the recessed shape, there is a fear in that resin burrs that entered the recessed portion during a resin burr removing step cannot be sufficiently removed and that voids may be generated by the burrs during mounting of a substrate, thereby causing a heat dissipation property to decline.

### SUMMARY OF THE INVENTION

The present invention has been made in view of the problems described above, and an object of the present invention is to provide a method of manufacturing a semiconductor device, which is capable of preventing thin burrs from adhering to a rear surface of an island.

The following measures are used in order to solve the above-mentioned problems.

First, according to one embodiment of the present invention, there is provided a method of manufacturing a semiconductor device in which an island for mounting a semiconductor chip thereon has a rear surface that is exposed from an encapsulating resin, the method including: molding a lead frame including the island, inner leads, and outer leads; mounting the semiconductor chip on the island; connecting the semiconductor chip to the inner leads via wires; and resin-encapsulating the island, the semiconductor chip, and the inner leads, the molding a lead frame including: placing a sheet material, which is to form the island, on a die; and pressing, against the sheet material, a mold including an inner punch, punch guides, and outer punches, to thereby mold simultaneously a recessed portion in contact with the inner punch, protruding walls in contact with the punch guides, and thin walled portions in contact with the outer punches.

Further, in the method of manufacturing a semiconductor device, the molding a lead frame includes using a mold having a variable level difference between the inner punch and the punch guides.

Further, in the method of manufacturing a semiconductor device, the molding a lead frame includes using a mold having a variable distance between the inner punch and the outer punches.

Further, in the method of manufacturing a semiconductor device, the resin-encapsulating the island, the semiconductor chip, and the inner leads includes forming a gate in a center of a cavity in a mold, forming the thin walled portions on a location lower than the center of the cavity, and injecting resin through the gate.

Through use of the measures described above, occurrence of the thin burrs on the rear surface side of the island can be suppressed and the effective area of the exposed portion of the island can be secured, thereby enabling the high heat dissipation property to be obtained.

### BRIEF DESCRIPTION OF THE DRAWINGS

FIG. 1 is a sectional view of a semiconductor device according to a first embodiment of the present invention.

FIG. 2 is a side view for illustrating a manufacturing step for a lead frame (island) used in the semiconductor device according to the first embodiment of the present invention.

FIG. 3 is a (transparent) plan view of the semiconductor device according to the first embodiment of the present invention.

FIG. 4 is a rear view of the semiconductor device according to the first embodiment of the present invention.

### DETAILED DESCRIPTION OF THE INVENTIONS

Now, description is given of an embodiment of the present invention with reference to the drawings.

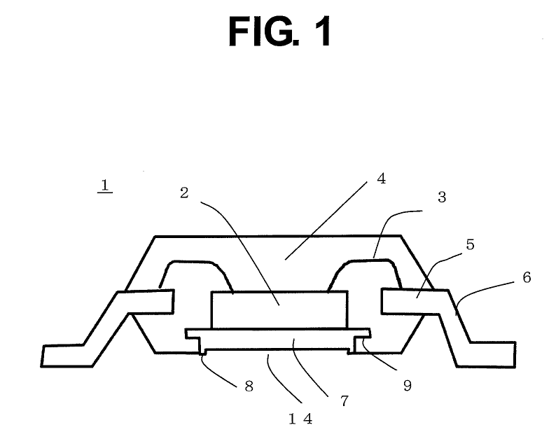

FIG. 1 is a sectional view of a semiconductor device according to a first embodiment of the present invention.

A semiconductor chip 2 is mounted on an island 7, and electrodes (not shown) on the semiconductor chip 2 are electrically connected to inner leads 5 via wires 3. The island 7, the semiconductor chip 2, and the wires 3 are covered with an encapsulating resin 4. Further, a rear surface of the island 7 is exposed from the encapsulating resin 4 so that heat dissipation property is enhanced. Outer leads 6 that extend from the inner leads 5 are also exposed from the encapsulating resin 4, and end portions of the outer leads 6 are connected to a wiring substrate or the like.

The semiconductor device 1 of the present invention has a feature in that, the island 7 has protruding walls 8 that protrude downward along an entire perimeter of the rear surface, a recessed portion 14 surrounded by the protruding walls 8, and thin walled portions 9 that laterally protrude from upper edges of side surfaces of the island 7. A front surface of the island 7 and upper surfaces of the thin walled portions 9 are on the same height level, forming a plane. The protruding walls 8 may be controlled to have a height of from 0.05 mm to 0.10 mm and a width of from 0.05 mm to 0.20 mm. By forming the protruding walls 8 having such height around the rear surface of the island 7, the protruding walls 8 are pressed against a lower mold for resin encapsulation (not shown) when the semiconductor chip 2 mounted on the island 7 is resin-encapsulated, which enables prevention of entrance of the encapsulating resin and suppression of occurrence of thin burrs from reasons described below.

Specifically, in the present invention, there are formed the thin walled portions 9, which laterally protrude from the upper edges of the side surfaces of the island 7, and serve to press the island 7 against the lower mold during the resin encapsulation. Although not shown, a gate through which the resin is injected is formed at a location near a longitudinal center of a cavity formed between an upper mold and the lower mold, and the resin is supplied therefrom to the molds around the gate. Since the thin walled portions 9 of the island 7 are located below the above-mentioned location near the longitudinal center, a volume of the resin above the thin walled portions 9 is significantly larger than a volume of the resin below the thin walled portions 9, pressing the island 7 against the lower mold, which results in prevention of the resin from entering the recessed portion 14 passing below the protruding walls 8.

As described above, in the present invention, the protruding walls that protrude downward and the recessed portion surrounded by the protruding walls are formed around the lower edges of the island 7, and the thin walled portions that laterally protrude are formed around the upper edges of the island 7. Occurrence of the thin burrs on the rear surface of the island can thus be suppressed and the concern about the reduction of the effective area of the exposed portion can be alleviated, thereby enabling the high heat dissipation property to be obtained.

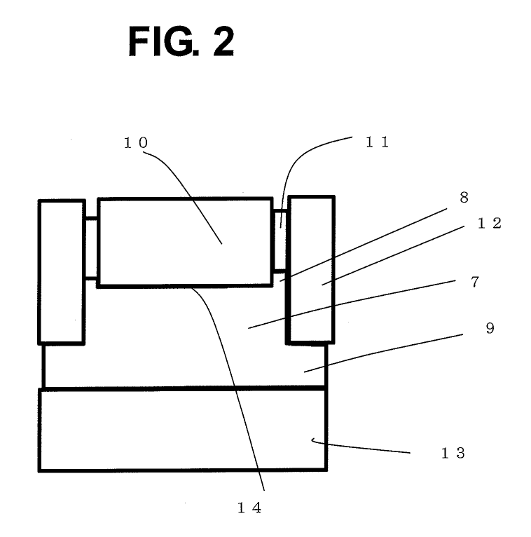

FIG. 2 is a side view for illustrating a molding step for the island portion of the semiconductor device.

In FIG. 2, the island 7 illustrated in FIG. 1 is illustrated upside down. The thickness of the island 7 is illustrated in an exaggerated manner. A sheet material made of copper or a copper alloy, which is a material of the island, is placed on a flat surface of a die 13 so that a semiconductor chip mounting surface of the island 7 faces downward. The rear surface of the island 7 is molded with a mold. The mold includes an inner punch 10, punch guides 11, and outer punches 12. The recessed portion 14 is formed on the rear surface of the island 7 by the inner punch 10. The punch guides 11 are formed on both sides of the inner punch 10 to determine the height of the protruding walls 8. The thin walled portions 9 are formed by the outer punches 12, which are arranged on outer sides of the punch guides 11.

Specifically, the recessed portion 14 is in abutment with the inner punch 10, the protruding walls 8 are in abutment with the punch guides 11, and the thin walled portions 9 are in abutment with the outer punches 12. In the present invention, the island 7 is pressed by both of the inner punch 10 and the outer punches 12, and thus a large amount of copper member overflows on the punch guides 11. The protruding walls 8 can hence have a maximum height of 0.10 mm, and because of the presence of the thin walled portions 9 formed simultaneously with the protruding walls 8, entrance of the encapsulating resin may be prevented and occurrence of the thin burrs may be suppressed during the resin encapsulation.

The depth of the recessed portion 14, the height of the protruding walls 8, and the thickness of the thin walled portions 9 may be adjusted by adjusting the relative height among the inner punch 10, the punch guides 11, and the outer punches 12 of the mold, and by adjusting the pressing pressure of the mold against the sheet material. In the mold used herein, a level difference between the inner punch 10 and the punch guides 11 may be variable, and the distance between the inner punch 10 and the outer punches 12 may be variable as well. As a result, there may be obtained protruding walls having a desired height and width.

Further, the inner leads 5, the outer leads 6, the island 7 are formed from the silver-plated sheet material made of copper or a copper alloy, through stamping. The island 7 is formed by being subjected to depression processing after the stamping. When necessary, warp correction is performed on the island 7 after the stamping. After the depression processing, the sheet material is cut to the frame size, and the manufacturing of the lead frame is finished.

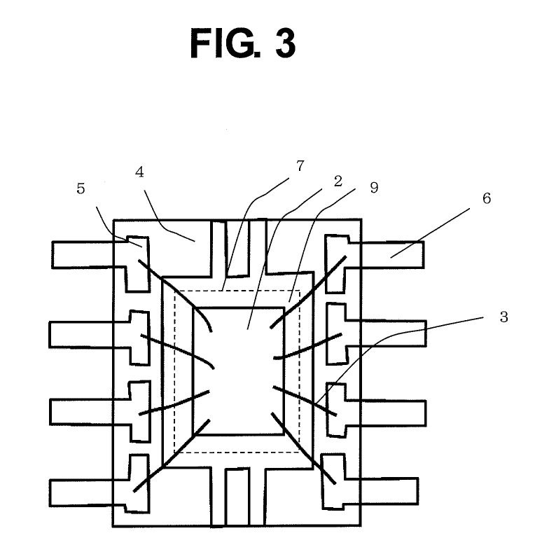

FIG. 3 is a transparent plan view of the semiconductor device according to the first embodiment of the present invention. The semiconductor chip 2 is mounted on the island 7 through intermediation of a conductive bonding film or an insulating bonding film. Electrodes (not shown) on the semiconductor chip 2 are electrically connected to the inner leads 5 via the wires 3 made of gold (Au) or copper (Cu). The island 7, the semiconductor chip 2, and the wires 3 are covered with the encapsulating resin 4. The outer leads 6 that extend from the inner leads 5 are exposed from the encapsulating resin 4, and the end portions of the outer leads 6 are connected to the wiring substrate or the like. Further, because the thin walled portions 9 are formed along the entire perimeter of the island 7, increasing the area of contact between the encapsulating resin 4 and the island 7 and improving adhesion therebetween, the thin walled portions 9 serve to prevent the island 7 from falling off the encapsulating resin 4.

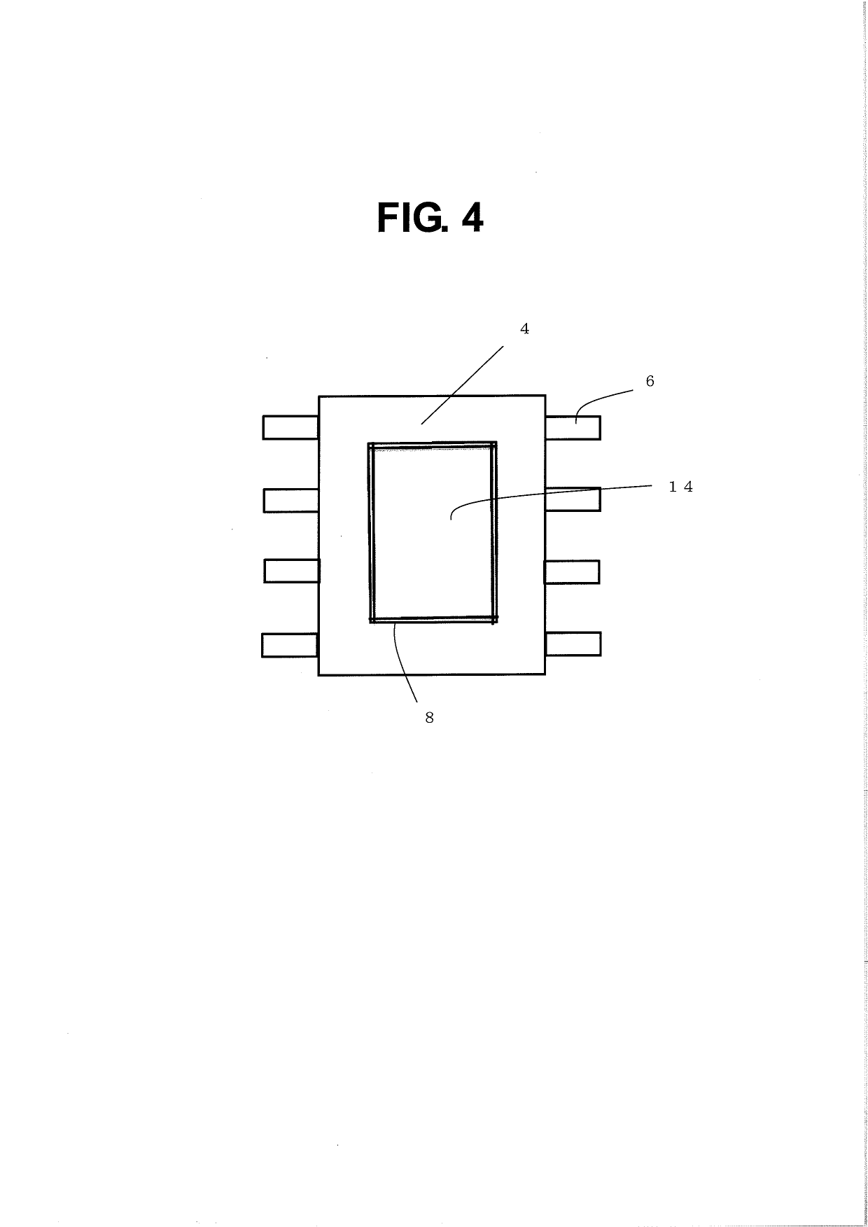

FIG. 4 is a rear view of the semiconductor device according to the first embodiment of the present invention.

A plurality of the outer leads 6 extend from the side surfaces of the encapsulating resin 4, and the island 7 having the protruding walls 8 formed along the entire perimeter thereof is arranged in a central part of the encapsulating resin. The recessed portion 14 on the rear surface of this island 7 is exposed so that high heat dissipation property can be secured.

What is claimed is:

1. A method of manufacturing a semiconductor device in which an island for mounting a semiconductor chip thereon has a rear surface that is exposed from an encapsulating resin, the method comprising:
molding a lead frame comprising the island, inner leads, and outer leads;
mounting the semiconductor chip on the island;
connecting the semiconductor chip to the inner leads via wires; and
resin-encapsulating the island, the semiconductor chip, and the inner leads,
the molding a lead frame comprising:
placing a sheet material, which is to form the island, on a die; and
pressing, against the sheet material, a mold comprising an inner punch, punch guides, and outer punches, to thereby mold simultaneously a recessed portion in contact with the inner punch, protruding walls in contact with the punch guides, and thin walled portions in contact with the outer punches.

2. A method of manufacturing a semiconductor device according to claim 1, wherein the molding a lead frame comprises using a mold having a variable level difference between the inner punch and the punch guides.

3. A method of manufacturing a semiconductor device according to claim 1, wherein the molding a lead frame comprises using a mold having a variable distance between the inner punch and the outer punches.

4. A method of manufacturing a semiconductor device according to claim 1, wherein the resin-encapsulating the island, the semiconductor chip, and the inner leads comprises forming a gate in a center of a cavity in a mold, forming the thin walled portions on a location lower than the center of the cavity, and injecting resin through the gate.

5. A semiconductor device, comprising:
an island comprising:
a rear surface exposed from an encapsulating resin;
protruding walls protruding downward around the rear surface;
a recessed portion surrounded by the protruding walls;
thin walled portions laterally protruding from upper edges around the island; and
a front surface;
a semiconductor chip mounted on the front surface of the island;
inner leads connected to the semiconductor chip by wires;
outer leads extending from each of the inner leads; and
a resin encapsulating, while exposing the rear surface of the island, the front surface and side surfaces of the island, the thin walled portions, the semiconductor chip, the inner leads, and the wires.
